(19) United States
(12) Patent Application Publication
(10) Pub. No.: US 2023/0197880 A1
(43) Pub. Date: Jun. 22, 2023

(54) SUBSTRATE SUPPORT PLATE FOR DEPOSITING MATERIAL ON EDGES OF A SUBSTRATE FACE

(71) Applicant: COMMISSARIAT A L'ENERGIE ATOMIQUE ET AUX ENERGIES ALTERNATIVES, Paris (FR)

(72) Inventors: Wilfried FAVRE, Grenoble Cedex 09 (FR); Frédéric JAY, Grenoble Cedex 09 (FR); Benjamin THIRIOT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/065,889

(22) Filed: Dec. 14, 2022

(30) Foreign Application Priority Data
Dec. 16, 2021 (FR) 21 13722

(51) Int. Cl. H01L 31/18; C23C 14/50; C23C 16/458

(52) U.S. Cl. CPC H01L 31/18; C23C 14/50; C23C 16/4582

(57) ABSTRACT

A plate configured to support at least one substrate during a deposition of material on the substrate, including at least:
a solid holding surface on which a main face of the substrate is intended to be placed during the deposition, the dimensions of which are smaller than those of the main face of the substrate so that edges of the main face of the substrate are not in contact with the solid holding surface;
connecting elements forming arms mechanically connecting the solid holding surface to a frame of the plate.

### TECHNICAL FIELD

The invention relates to the field of depositing materials, in particular for the production of photovoltaic cells. The invention applies in particular to the production of photovoltaic cells with passivating contacts, and in particular to the deposition of thin layers on the edge of substrates in order to maximise the lateral transport and optical confinement of charges.

### PRIOR ART

A photovoltaic cell is made from a substrate, or sheet or wafer, of a semi-conductor on which thin films are deposited. There are many different types of plates used to support the substrates for making these deposits.

When a deposition is to be performed on both sides (font and back faces) of the substrate, for example in a PVD (Physical Vapour Deposition) process, an “open” plate is used, i.e. forming access to part of the face of the substrate on the plate side. On such a plate, the substrate is generally held at the edges of the substrate. Such a plate is described for example in document WO 2019/219127 A1.

Document DE 10 2020 101 264 A1 also describes an “open” plate including, in addition to a support part for the substrate edges, a central support element masking a dividing line between two substrate parts. Such a plate is suitable for producing cells which are designed to be cut along the dividing line to obtain half-cells.

These “open” plates are not suitable however, if material needs to be deposited on the edges of a face of the substrate.

### DISCLOSURE OF THE INVENTION

Thus there is a need to propose a support plate, or holder, for at least one substrate which enables material to be deposited on edges of one face of the substrate without covering the remainder of this face with the material.

For this purpose, one embodiment proposes a plate configured to support at least one substrate during a deposition of material on the substrate, including at least:
a solid holding surface on which a main face of the substrate is intended to be placed during the deposition, and the dimensions of which are smaller than those of the main face of the substrate so that edges of the main face of the substrate are not in contact with the solid holding surface;
connecting elements forming arms mechanically connecting the solid holding surface to a frame or base of the plate.

When depositing material on the substrate held in such a plate, it is therefore possible to position the deposited material against the edges of the main face of the substrate which is on the side of the solid holding surface, without covering the remainder of this main face of the substrate with material.

The term “substrate” denotes a sheet or wafer of material, for example a semi-conductor such as silicon, on which one or more elements may have been deposited (thin films, metal contacts, etc.).

Such a plate is used advantageously to deposit an anti-reflective coating, or more generally one or more thin layers of material(s), on edges of a silicon wafer intended to form a photovoltaic cell.

The plate further comprises empty parts arranged around the solid holding surface and configured to be arranged in front of the edges of the main face of the substrate.

The solid holding surface may have a square shape and the connecting elements may extend from corners of the solid holding surface and/from sides of the solid holding surface.

The connecting elements can have a thickness greater than that of the solid holding surface and can form raised portions, or embossed portions, on the side of the solid holding surface on which the substrate is intended to be placed. Such raised portions allow the substrate to be guided and held in a centred position on the solid holding surface.

The raised portions of the connecting elements can be removed. Thus, it is possible to modify the shape and/or dimensions of these raised portions according to the dimensions of the substrate held by the plate.

The plate may be configured to hold a plurality of substrates during the deposition of material on the substrates, and may include a plurality of solid holding surfaces spaced apart from one another and held mechanically on one another and on the frame by the connecting elements which join together, and the solid holding surfaces which are adjacent to the frame may be held directly on the frame by a portion of the connecting elements.

The plate may be configured to support at least one substrate for phovoltaic cell having a standard shape.

Another embodiment concerns a system comprising at least one plate and at least one substrate hold by the plate.

Another embodiment relates to a method for depositing material on edges of a face of at least one substrate, including at least:
depositing substrate on a plate as described above;
placing the plate in a deposition chamber of a deposition facility;
depositing material on the edges of the main face of the substrate which are not in contact with the solid holding surface.

The deposition facility may be of the PVD, PECVD or ALD type.

Another embodiment relates to a method for producing at least one photovoltaic cell, including the implementation of a deposition process as described above.

Throughout the document, the term “on” is used without distinguishing the orientation in space of the element to which this term refers. For example, in the feature “on a face of the substrate”, this face of the substrate is not necessarily oriented upwards but may correspond to a face oriented in any direction. Furthermore, the deposition of a first element on a second element should be understood as being able to correspond to the deposition of the first element directly against the second element, without any intermediate element between the first and second elements, or as meaning the deposition of the first element on the second element with one or more intermediate elements disposed between the first and second elements.

### BRIEF DESCRIPTION OF THE DRAWINGS

The present invention will be better understood by reading the description of exemplary embodiments which are given purely by way of example and are in no way limiting with reference to the accompanying drawings in which:

FIGS. 1 and 2 show a plate configured to support at least one substrate during deposition of material on the substrate, according to a first embodiment;

FIG. 3 shows a profile view of a substrate placed on a solid holding surface of a plate;

FIGS. 4 and 5 show a plate configured to support at least one substrate during a deposition of material on the substrate according to a second embodiment;

FIGS. 6 to 8 show different embodiments of connecting elements of a plate.

Identical, similar or equivalent parts of the various figures described in the following have the said reference numerals so as to facilitate the passage from one figure to another.

The different parts shown in the figures are not necessarily shown on a uniform scale, in order to make the figures more readable.

The different possibilities (variants and embodiments) should not be understood to be exclusive from one another and may be combined with one another.

### DETAILED DESCRIPTION OF PARTICULAR EMBODIMENTS

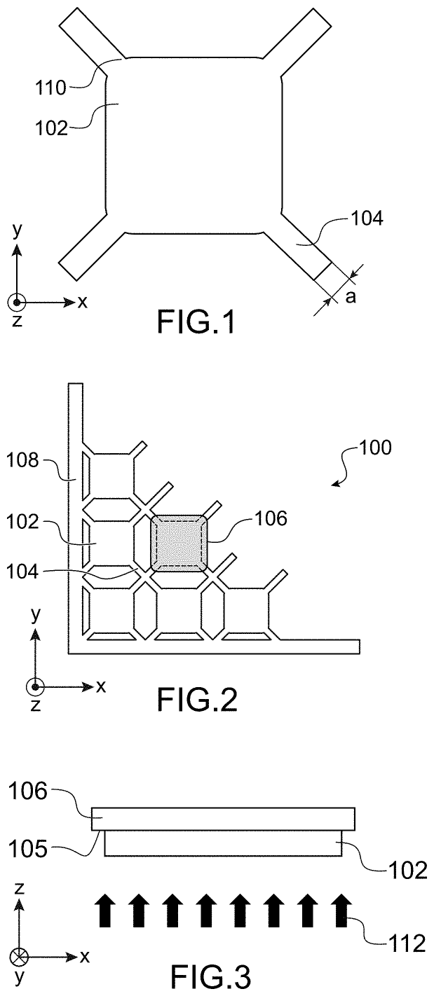

A plate 100, configured to support at least one substrate during the deposition of material on the substrate, according to a first embodiment is described below in connection with FIGS. 1 and 2. FIG. 1 shows a top view of a solid holding surface 102 and connecting elements 104 of the plate 100 according to the first embodiment. FIG. 2 shows a top view of a part of the plate 100 according to the first embodiment.

The plate 100 is configured to hold or support at least one substrate during a deposition of material on the substrate. In the exemplary embodiment described here, the plate 100 is configured to simultaneously hold a plurality of substrates in order to collectively deposit material on the edges 105 of one face of each of these substrates. In FIG. 2, one of the substrates subjected to the deposition process and arranged on the plate 100 is shown and denoted by reference numeral 106.

The substrate 106 may correspond to a standard photovoltaic cell substrate, i.e. having a standard shape and standard dimensions, e.g. corresponding to a wafer of one of the following standards: M12, M1, M9, M6, etc.

The plate 100 thus includes a plurality of solid holding surfaces 102 on each of which a main face of one of the substrates 106 is intended to be arranged during the deposition process. The dimensions of the surfaces 102 are smaller than those of this main face of the substrate 106 so that edges 105 of said main face of the substrate 106 are not in contact with the surface 102. These edges 105 can form, in a plane parallel to said main face of the substrate 106, a contour with a width less than or equal to 500 μm, and advantageously between 100 μm and 500 μm.

The plate 100 may comprise empty part arranged around the solid holding surfaces 102 and configured to be arranged in front of the edges 105 of the main face of each substrate 106.

The number of holding surfaces 102 of the plate 100 is a function of the dimensions of the plate 100 and the dimensions of each of the surfaces 102 (and therefore of the dimensions of the substrates 106). For example, the number of holding surfaces 102 of the plate 100 may be between 4 and 48.

The plate 100 is for example mainly made of stainless steel or titanium.

The plate 100 also has connecting elements 104 forming arms mechanically connecting each of the surfaces 102 to a frame 108 of the plate 100, either directly for the holding surfaces 102 which are adjacent to the frame 108, or via other holding surfaces 102 and other connecting elements 104 for the holding surfaces 102 which are not adjacent to the frame 108. In the example shown in FIG. 2, five of the holding surfaces 102 shown are adjacent to the frame 108 and are connected mechanically thereto via connecting elements 104, and one of the holding surfaces 102 (the one on which the substrate 106 is shown) is not adjacent to the frame 108 and is mechanically connected thereto via the other holding surfaces 102 and other connecting elements 104. At the intersection of the connecting elements, it is possible to provide more rigid elements in order to limit or eliminate mechanical deformations linked to the weight of the surfaces 102 and the substrates 106.

Thus, the plate 100 has, in this exemplary embodiment, a plurality of solid holding surfaces 102 spaced apart from each other and held mechanically on one another and on the frame 108 by the connecting elements 104 which join together.

In the exemplary embodiment shown in FIGS. 1 and 2, each of the holding surfaces 102 is square, and the connecting elements extend from four corners 110 of the holding surface 102.

In order to minimise the surface of the substrate(s) 106 which will be obscured by the connecting elements 104 during the deposition of material, the width (referenced “a” in FIG. 1) of the connecting elements 104 is selected to be as small as possible, whilst ensuring that this width is sufficient to provide sufficient mechanical holding of the surface(s) 102 and substrate(s) 106 disposed thereon.

The plate 100 is used in particular when carrying out a method of depositing material on the edges 105 of one face of at least one substrate 106, the method including at least the implementation of the following steps:
depositing the substrate 106 on the plate 100;
placing the plate 100 in a deposition chamber of a depositing facility for example of the PVD, PECVD or ALD type;
depositing material(s) on the edges 105 of the main face of the substrate 106 which are not in contact with the surface 102.

The plate 100 is advantageously used for depositing one or more materials on substrates 106 intended to form photovoltaic cells, for example of the type with passivating contacts. The substrate 106 can in particular correspond to a silicon sheet or wafer, and the material deposited on the edges 105 of the substrate 106 may correspond in particular to an anti-reflective material, or more generally one or more thin layers of material(s).

FIG. 3 shows a profile view of the substrate 106 deposited on the surface 102 during the deposition of material on the edges 105 of the substrate 106. The arrows with reference numeral 112 represent the material to be deposited on the edges 105 and sent to the main face of the substrate 106 placed against the surface 102 and which includes the edges 105.

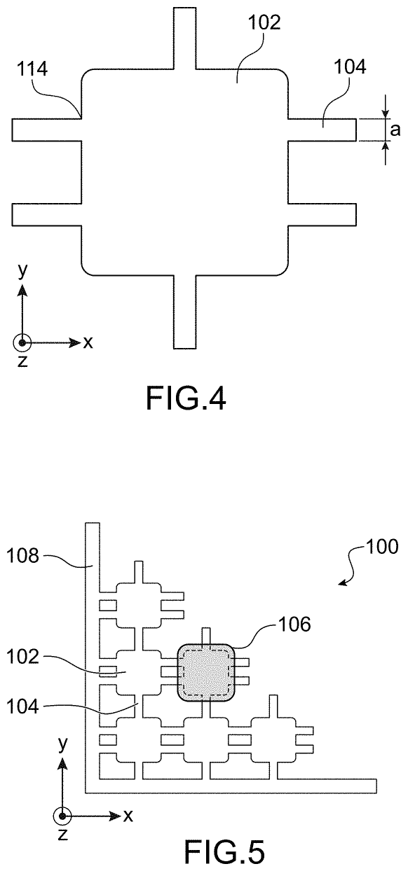

A substrate holding plate 100 according to a second embodiment is described below in connection with FIGS. 4 and 5. FIG. 4 shows a top view of a solid holding surface 102 and connecting elements 104 of the plate 100 according to the second embodiment. FIG. 5 shows a top view of part of the plate 100 according to the second embodiment.

Compared to the first embodiment described above, the connecting elements 104 extend from sides 114 of the solid holding surface. Other features of the plate 100 according to this second embodiment are similar to those described above for the first embodiment.

Regardless of the configuration of the plate 100 (first or second embodiment or other), the connecting elements 104 advantageously have a thickness greater than that of the surface 102 and form raised, or embossed, portions 116 on the side of the surface 102 on which the substrate 106 is intended to be placed. Thus, the connecting elements 104 allow good centring of the substrate 106 on the surface 102, both by guiding the substrate 106 when the substrate 106 is placed on the surface 102, and also by holding this substrate 106 in its centred position on the surface 102 when the plate 100 is moved.

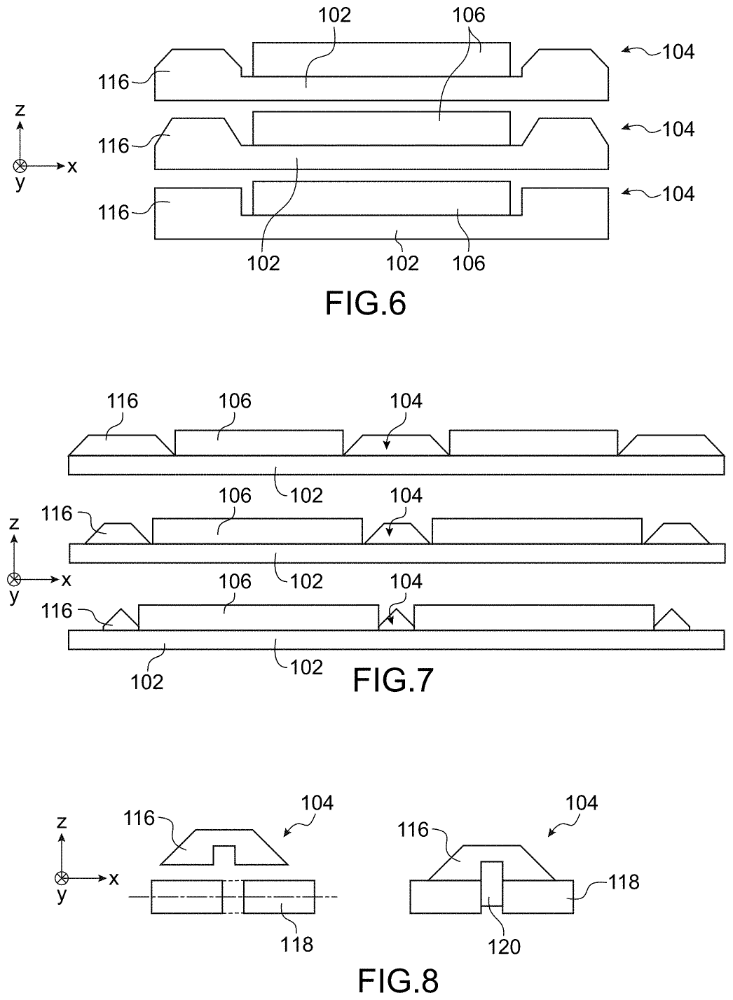

FIG. 6 shows three embodiments of such connecting elements 104 including raised portions 116. The profile of these raised portions 116 is for example pyramidal, a truncated pyramid, rectangular, polygonal or any other shape.

The shape of the connecting elements 104, and in particular of the raised portions 116, may in particular be selected according to the size of the substrate(s) 106. FIG. 7 shows three examples of embodiments of connecting elements 104 whose raised portions 116 have different shapes and dimensions suitable for substrates 106 of different dimensions. For a given dimensional space, the dimensions of the raised portions 116 of the connecting elements 104 can thus be larger when the substrates 106 are smaller.

Regardless of the form and dimensions of the connecting elements 104, the raised portions 116 of the connecting elements 104 can be removable. Thus, it is possible to select these raised portions 116 as a function of the shape and/or dimensions of the substrate(s) 106 on which the deposit is made. By taking the exemplary embodiments shown in FIG. 7, it is possible to select as a function of the dimensions of the substrates 106, the raised portions 116 whose dimensions best fit those of the substrates 106.

FIG. 8 shows an embodiment of such a connecting element 104 comprising a removable raised portion 116 and which is fixed to a fixed portion 118 of the connecting element 104 by a holding element 120 passing through the fixed portion 118. Other ways of attaching the raised portions 116 to the fixed portions 118 of the connecting elements 104 may be envisaged.

1. A plate configured to support at least one substrate during a deposition of material on the substrate, including at least:
a solid holding surface against which a main face of the substrate is intended to be placed during the deposition, the dimensions of which are smaller than those of the main face of the substrate so that edges of the main face of the substrate are not in contact with the solid holding surface;
empty parts arranged around the solid holding surface and configured to be arranged in front of the edges of the main face of the substrate;
a frame
connecting elements forming arms mechanically connecting the solid holding surface to the frame of the plate.

2. The plate according to claim 1, wherein the solid holding surface has a square shape, and wherein the connecting elements extend from the corners of the solid holding surface or from the sides of the solid holding surface.

3. The plate according to claim 1, wherein the connecting elements have a thickness greater than that of the solid holding surface and form raised portions on the side of the solid holding surface on which the substrate is intended to be placed.

4. The plate according to claim 3, wherein the raised portions of the connecting elements are removable.

5. The plate according to claim 1, configured to hold a plurality of substrates during a deposition of material on the substrates, including a plurality of solid holding surfaces spaced apart from one another and held mechanically to one another and to the frame by the connecting elements which joint together, and wherein the solid holding surfaces which are adjacent to the frame are directly held on the frame by a portion of the connecting elements.

6. The plate according to claim 1, wherein the plate is configured to support at least one photovoltaic cell standard wafer.

7. A system comprising at least one plate according to claim 1 and at least one substrate hold by the plate.

8. Method for depositing material on the edges of a face of at least one substrate, including at least:
depositing the substrate on a plate according to claim 1;
placing the plate in a deposition chamber of a deposition facility;
depositing material on the edges of the main face of the substrate which are not in contact with the solid holding surface of the plate.

9. Method according to claim 8, wherein the deposition equipment is of the PVD, PECVD or ALD type.

10. Method of producing at least one photovoltaic cell, including performing a deposition method according to claim 7, and wherein the substrate is a photovoltaic cell standard wafer.
